(19) United States
(12) Patent Application Publication
(10) Pub. No.: US 2025/0393454 A1
(43) Pub. Date: Dec. 25, 2025

(54) DISPLAY DEVICE, METHOD OF MANUFACTURING DISPLAY DEVICE, AND ELECTRONIC DEVICE COMPRISING DISPLAY DEVICE

(71) Applicant: Samsung Display Co., Ltd., Yongin-si (KR)

(72) Inventors: Yeon Tae KIM, Yongin-si (KR); Dae Hyun KIM, Yongin-si (KR); Hyun Jin SONG, Yongin-si (KR); Kwang Jin JEONG, Yongin-si (KR)

(21) Appl. No.: 19/212,645

(22) Filed: May 19, 2025

(30) Foreign Application Priority Data
Jun. 20, 2024 (KR) 10-2024-0080262

(51) Int. Cl. H10K 59/80; H10H 29/01; H10H 29/855

(52) U.S. Cl. CPC H10K 59/8793; H10H 29/0363; H10H 29/8552; H10K 59/8792

(57) ABSTRACT

A display device includes: a display panel; a polarizing layer on the display panel; an adhesive layer on the polarizing layer; and a light blocking layer, at least a portion of the light blocking layer being on the adhesive layer, wherein the polarizing layer includes a first polarizing portion that does not overlap the light blocking layer and a second polarizing portion that overlaps the light blocking layer in a plan view, and the second polarizing portion has a transmittance higher than a transmittance of the first polarizing portion with respect to ultraviolet (UV) light.

### CROSS-REFERENCE TO RELATED APPLICATION

The present application claims priority to and the benefit of Korean Patent Application No. 10-2024-0080262, filed on Jun. 20, 2024, in the Korean Intellectual Property Office, the entire disclosure of which is incorporated herein by reference.

### BACKGROUND

### 1. Field

Aspects of some embodiments of the present disclosure relate to a display device, a method of manufacturing the display device, and an electronic device comprising the display device.

### 2. Description of the Related Art

As interest in information display increases, research and development on display devices is continuously being conducted.

Display devices may include a plurality of layers. Some of the plurality of layers may be directly adjacent to each other. When the plurality of layers are not properly adhered, a risk of a separation phenomenon or the like of some layers may occur.

The above information disclosed in this Background section is only for enhancement of understanding of the background and therefore the information discussed in this Background section does not necessarily constitute prior art.

### SUMMARY

Aspects of some embodiments of the present disclosure include a display device, a method of manufacturing the display device, and an electronic device comprising the display device in which layers included in the display device are relatively stably adhered to each other and thus structural stability may be relatively improved.

Aspects of some embodiments of the present disclosure include a display device, a method of manufacturing the display device, and an electronic device comprising the display device in which structural defects of the display device may be prevented or reduced.

According to some embodiments of the present disclosure, a display device may include a display panel, a polarizing layer on the display panel, an adhesive layer on the polarizing layer, and a light blocking layer, at least a portion of the light blocking layer being on the adhesive layer. According to some embodiments, the polarizing layer may include a first polarizing portion that does not overlap the light blocking layer and a second polarizing portion that overlaps the light blocking layer in a plan view. According to some embodiments, the second polarizing portion may have a transmittance higher than a transmittance of the first polarizing portion with respect to ultraviolet (UV) light.

According to some embodiments, the first polarizing portion may block light having a wavelength of 380 nm. According to some embodiments, the second polarizing portion may transmit light having a wavelength of 380 nm.

According to some embodiments, the polarizing layer may include a UV blocking portion. According to some embodiments, the UV blocking portion may be included in the first polarizing portion and may not be included in the second polarizing portion.

According to some embodiments, the polarizing layer may include one or more of a triacetylcellulose (TAC) film and a polyvinyl alcohol (PVA) film.

According to some embodiments, the adhesive layer may include one or more of optically clear resin (OCR) and optically clear adhesive (OCA).

According to some embodiments, the display device may further include a cover glass covering the adhesive layer and the light blocking layer. According to some embodiments, the cover glass may overlap the first polarizing portion and the second polarizing portion in a plan view, and may be configured to transmit UV light.

According to some embodiments, the display device may include a display area where light is provided and a non-display area surrounding at least a portion of the display area. According to some embodiments, the first polarizing portion and the second polarizing portion may be spaced apart in a direction in which the display area and the non-display area are spaced apart from each other.

According to some embodiments, the display device may further include a driving circuit part on an area of the display panel where the polarizing layer is not located. According to some embodiments, the driving circuit part may be on a side of the display area and may overlap the light blocking layer in a plan view.

According to some embodiments, the second polarizing portion, the adhesive layer, and the light blocking layer may overlap each other in a plan view. According to some embodiments, the first polarizing portion and the adhesive layer may overlap each other and may not overlap the light blocking layer in a plan view.

According to some embodiments, the second polarizing portion may be only on a side of the first polarizing portion.

According to some embodiments, the second polarizing portion may entirely surround the first polarizing portion.

According to some embodiments, the second polarizing portion may surround two or more sides of the first polarizing portion and may not surround a side.

According to some embodiments, an end of the polarizing layer and an end of the adhesive layer may overlap in a plan view.

According to some embodiments of the present disclosure, a method of manufacturing a display device may include forming a plurality of layers on a display panel, in which the plurality of layers include a polarizing layer, an adhesive layer on the polarizing layer, and a light blocking layer, at least a portion of the light blocking layer being on the adhesive layer, and curing the adhesive layer. According to some embodiments, the polarizing layer may include a first polarizing portion that does not overlap the light blocking layer and a second polarizing portion that overlaps the light blocking layer in a plan view. According to some embodiments, curing may include applying UV light to a portion of the adhesive layer through an opening formed in a stage under the display panel and the second polarizing portion.

According to some embodiments, in curing, the opening may not overlap the first polarizing portion and may overlap the second polarizing portion in a plan view.

According to some embodiments, the light blocking layer may not overlap the first polarizing portion and may overlap the second polarizing portion in a plan view.

According to some embodiments, the second polarizing portion may be configured to transmit UV light. According to some embodiments, the first polarizing portion may be configured to block UV light.

According to some embodiments, the plurality of layers may further include a cover glass covering the light blocking layer and the adhesive layer. According to some embodiments, the cover glass may be configured to transmit UV light.

According to some embodiments, curing may further include applying UV light to another portion of the adhesive layer that does not overlap the light blocking layer in a first application direction. According to some embodiments, the UV light applied to the portion of the adhesive layer through the opening and the second polarizing portion may be applied in a second application direction different from the first application direction.

According to some embodiments, the plurality of layers may further include a driving circuit part configured to drive a pixel included in the display panel. According to some embodiments, in curing, the driving circuit part may not overlap the opening and may overlap the light blocking layer in a plan view.

According to some embodiments of the present disclosure, an electronic device may comprise a processor configured to provide input image data; a display device configured to display an image based on the input image data; and a power supply configured to supply power to the display device. The display device may comprise: a display panel; a polarizing layer on the display panel; an adhesive layer on the polarizing layer; and a light blocking layer, at least a portion of the light blocking layer being on the adhesive layer. The polarizing layer may include a first polarizing portion that does not overlap the light blocking layer and a second polarizing portion that overlaps the light blocking layer in a plan view. The second polarizing portion may a transmittance higher than a transmittance of the first polarizing portion with respect to ultraviolet (UV) light.

According to some embodiments of the present disclosure, a display device, a method of manufacturing the display device, and an electronic device comprising the display device in which layers included in the display device may be relatively stably or securely adhered to each other and thus structural stability may be relatively improved may be provided.

According to some embodiments of the present disclosure, a display device and a manufacturing method of the display device in which a structural defect of the display device may be prevented or reduced may be provided.

### BRIEF DESCRIPTION OF THE DRAWINGS

The above and other features of embodiments according to the present disclosure will become more apparent by describing in further detail aspects of some embodiments thereof with reference to the accompanying drawings, in which:

FIG. 1 is a schematic plan view illustrating a display device according to some embodiments;

FIG. 2 is a schematic cross-sectional view illustrating a display device according to some embodiments;

FIG. 3 is a schematic block diagram illustrating a polarizing layer according to some embodiments;

FIGS. 4 to 6 are schematic plan views illustrating a polarizing layer according to some embodiments;

FIG. 7 is a flowchart illustrating aspects of a method of manufacturing a display device according to some embodiments; and

FIGS. 8 and 9 are schematic cross-sectional views for each process operation illustrating a method of manufacturing a display device according to some embodiments.

FIG. 10 is a block diagram of an electronic device according to an embodiment.

FIG. 11 shows schematic diagrams of electronic devices according to various embodiments.

### DETAILED DESCRIPTION

The disclosure may be modified in various manners and have various forms. Therefore, specific embodiments will be illustrated in the drawings and will be described in detail in the specification. However, it should be understood that the disclosure is not intended to be limited to the disclosed specific forms, and the disclosure includes all modifications, equivalents, and substitutions within the spirit and technical scope of the disclosure.

Terms of “first”, “second”, and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component. In the following description, the singular expressions include plural expressions unless the context clearly dictates otherwise.

It should be understood that in the present application, a term of “include”, “have”, or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof in advance. In addition, a case where a portion of a layer, a layer, an area, a plate, or the like is referred to as being “on” another portion, it includes not only a case where the portion is “directly on” another portion, but also a case where there is further another portion between the portion and the other portion. In addition, in the present specification, when a portion of a layer, a layer, an area, a plate, or the like is formed on another portion, a forming direction is not limited to an upper direction but includes forming the portion on a side surface or in a lower direction. On the contrary, when a portion of a layer, a layer, an area, a plate, or the like is formed “under” another portion, this includes not only a case where the portion is “directly beneath” another portion but also a case where there is further another portion between the portion and the other portion.

The disclosure relates to a display device, a method of manufacturing the display device, and an electronic device comprising the display device. Hereinafter, a display device, a method of manufacturing the display device, and an electronic device comprising the display device according to some embodiments is described with reference to the accompanying drawings.

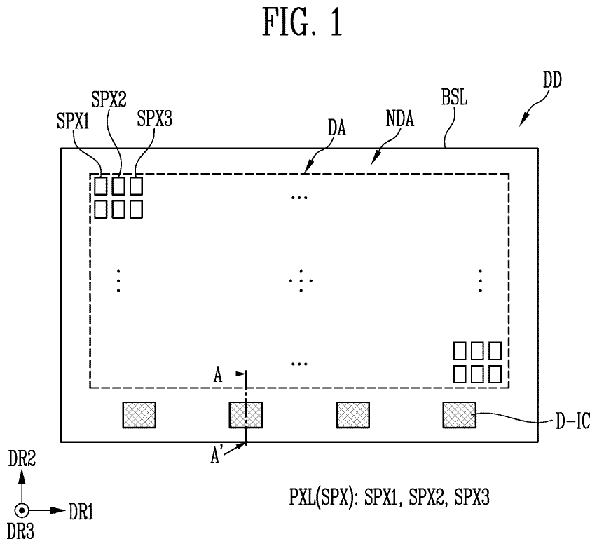

FIG. 1 is a schematic plan view illustrating a display device according to some embodiments.

Referring to FIG. 1, the display device DD may include a base layer BSL and a pixel PXL located on the base layer BSL. The display device DD may further include a driving circuit part D-IC, lines, and pads.

The display device DD (or the base layer BSL) may include a display area DA and a non-display area NDA. The non-display area NDA refers to an area other than the display area DA. The non-display area NDA may surround (e.g., in a periphery or outside a footprint of) at least a portion of the display area DA.

The base layer BSL may form a base surface of the display device DD. The base layer BSL may be a rigid or flexible substrate or film. For example, the base layer BSL may include a glass material. Alternatively, the base layer BSL may include a silicon material. Alternatively, the base layer BSL may include polyimide. However, embodiments according to the present disclosure are not limited thereto.

The display area DA may mean an area where the pixel PXL is located. The non-display area NDA may refer to an area where the pixel PXL is not located (e.g., in a periphery or outside a footprint of the display area DA). The driving circuit part, the line, and the pads connected to the pixel PXL of the display area DA may be located in the non-display area NDA.

According to some embodiments, the pixel PXL (or sub-pixels SPX) may be arranged according to a stripe or PENTILE™ arrangement structure, but are not limited thereto, and various embodiments may be applied to the disclosure.

According to some embodiments, the pixel PXL (or the sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one of the first sub-pixel SPX1, the second sub-pixel SPX2, or the third sub-pixel SPX3 may form a pixel unit configured to emit light of various colors.

Each of the first sub-pixel SPX1, the second sub-pixel SPX2, and the third sub-pixel SPX3 may emit light of one color.

For example, the first sub-pixel SPX1 may be a red pixel emitting light of red (for example, first color), the second sub-pixel SPX2 may be a green pixel emitting light of green (for example, second color), and the third sub-pixel SPX3 may be a blue pixel emitting light of blue (for example, third color). The red pixel may provide light of a wavelength range of 600 nanometers (nm) to 750 nm. The green pixel may provide light of a wavelength band of 480 nm to 560 nm. The blue pixel may provide light of a wavelength range of 370 nm to 460 nm.

According to some embodiments, the number of second sub-pixels SPX2 may be greater than the number of first sub-pixels SPX1 and the number of third sub-pixels SPX3. However, the color, type, number, and/or the like of the first sub-pixel SPX1, the second sub-pixel SPX2, and the third sub-pixel SPX3 forming each pixel unit are/is not limited to a specific example.

The driving circuit part D-IC may be located on one side of the display area DA. The driving circuit part D-IC may be placed in the non-display area NDA.

The driving circuit part D-IC may include a scan driver and a data driver. The scan driver may be configured to supply a scan signal to the pixel PXL. The data driver may be configured to supply a data signal to the pixel PXL. According to some embodiments, the pixel PXL may be electrically connected to the driving circuit part D-IC and may emit light based on an electrical signal provided from the driving circuit part D-IC.

According to some embodiments, the display device DD may further include a touch sensor. In this case, the display device DD may further include a touch driving circuit part configured to drive the touch sensor. According to some embodiments, the touch driving circuit part may be located on one of other sides of the display area DA where the driving circuit part D-IC that drives the pixel PXL is not located.

According to embodiments of the present disclosure, the display device DD may be incorporated into or operate as part of an electronic device configured to display images, such as a smartphone, tablet, laptop, monitor, head-mounted display (e.g., virtual reality or augmented reality display), watch, and the like.

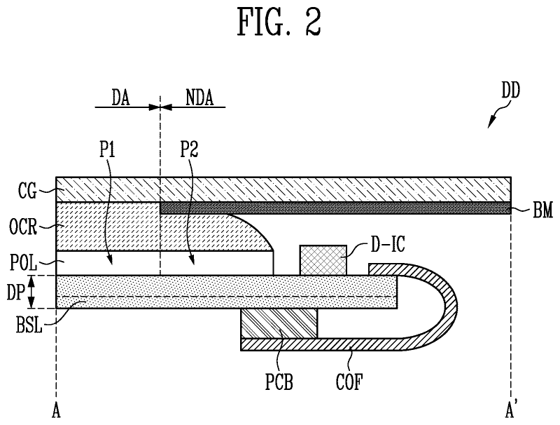

With reference to FIGS. 2 to 6, a display device DD including a polarizing layer POL and an adhesive layer OCR according to some embodiments is described.

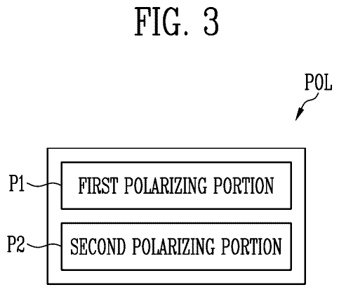

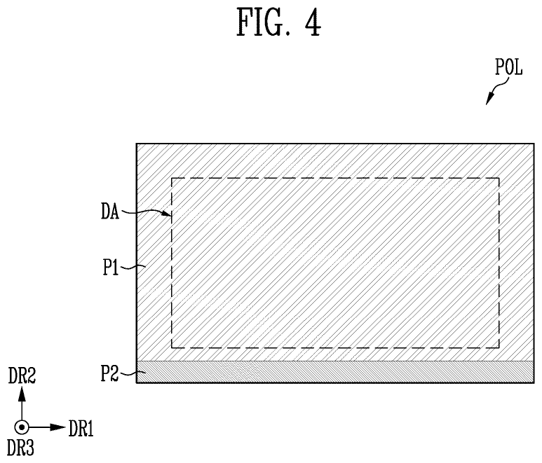

FIG. 2 is a schematic cross-sectional view illustrating aspects of a display device according to some embodiments. FIG. 2 is a schematic cross-sectional view along the line A˜A′ of FIG. 1. FIG. 3 is a schematic block diagram illustrating a polarizing layer according to some embodiments. FIGS. 4 to 6 are schematic plan views illustrating a polarizing layer according to some embodiments.

Referring to FIGS. 2 to 6, the display device DD may include a display panel DP, a polarizing layer POL, an adhesive layer OCR, a light blocking layer BM, a cover glass CG, the driving circuit part D-IC, a connection film COF, and a circuit board PCB.

The display panel DP may be arranged across the display area DA and the non-display area NDA. The display panel DP may be configured to emit light. The display panel DP may include the base layer BSL, and a pixel circuit and a light source such as a light emitting element on the base layer BSL. The pixel circuit may include circuit elements capable of driving the pixel PXL (or the light emitting element LD). The light source may include an inorganic light emitting diode including an inorganic material, and may include an organic light emitting diode including an organic material. However, embodiments according to the present disclosure are not limited to a specific example.

The polarizing layer POL may be located on the display panel DP. The polarizing layer POL may be arranged across the display area DA and the non-display area NDA. The polarizing layer POL may be located between the adhesive layer OCR and the display panel DP.

The polarizing layer POL may include a material having various polarizing properties. The polarizing layer POL may have a structure in which two or more layers are stacked.

For example, the polarizing layer POL may include one or more of a triacetylcellulose (TAC) film and a polyvinyl alcohol (PVA) film. According to some embodiments, the polarizing layer POL may have a structure in which first TAC film layer/PVA film layer/second TAC film layer are sequentially arranged. However, the disclosure is not limited thereto. According to some embodiments, the polarizing layer POL may further include an upper protective film and a lower protective film, may further include an adhesive layer for adhering a portion of layers forming the polarizing layer POL, and may further include an additional functional layer such as an anti-reflective film.

According to some embodiments, a first polarizing portion P1 of the polarizing layer POL may further include a UV blocking portion. A material for forming the UV blocking portion may include various materials commonly known in the art. For example, the UV blocking portion may not be located on a second polarizing portion P2, and may be arranged or coated on one of layers forming the first polarizing portion P1. For example, when the polarizing layer POL has a structure in which the first TAC film layer/PVA film layer/second TAC film layer are sequentially arranged, the UV blocking portion may be arranged or coated on one surface of one or more of the first TAC film layer, the PVA film layer, and the second TAC film layer.

The polarizing layer POL may include the first polarizing portion P1 and the second polarizing portion P2.

The first polarizing portion P1 and the second polarizing portion P2 may be spaced apart from each other in a direction in which a plane where the base layer BSL is located extends. For example, the first polarizing portion P1 and the second polarizing portion P2 may be spaced apart from each other in a direction in which the display area DA and the non-display area NDA are spaced apart from each other.

The plane defined in this specification may be a direction extending in a first direction DR1 and a second direction DR2 and may be defined based on the plane where the base layer BSL is located. According to some embodiments, a third direction DR3 may be a thickness direction of the base layer BSL, and the third direction DR3 may be a light emission direction of the display device DD. The phrase “in a plan view” or “when viewed in a plan view” may refer to a view toward the display device along the third direction DR3.

The first polarizing portion P1 and the second polarizing portion P2 may have different light transmittances. For example, the second polarizing portion P2 may have a transmittance higher than that of the first polarizing portion P1 with respect to ultraviolet (UV) light. According to some embodiments, a wavelength band of UV light may be about 100 nm to about 400 nm. The wavelength band of UV light may be a wavelength band including a wavelength of about 380 nm. For example, the second polarizing portion P2 may have a transmittance greater than that of the first polarizing portion P1 with respect to light of about 380 nm. According to some embodiments, the first polarizing portion P1 may not transmit (or may not substantially transmit) UV light. The first polarizing portion P1 may block light having a wavelength of 380 nm, and the second polarizing portion P2 may transmit light having a wavelength of 380 nm.

For example, the first polarizing portion P1 may include a first polarizing layer and a UV blocking portion. The second polarizing portion P2 may include a second polarizing layer, and may not include a UV blocking portion. According to some embodiments, the first polarizing layer and the second polarizing layer may include the same material. Accordingly, the first polarizing portion P1 and the second polarizing portion P2 may include the same layer, and the UV blocking portion may be formed only in the first polarizing portion P1. According to some embodiments, the UV blocking portion may be a UV blocking film. Alternatively, according to some embodiments, the UV blocking portion may be a coating film formed in a portion of the first polarizing layer. Alternatively, according to some embodiments, the UV blocking portion may be a UV blocking material included in the first polarizing layer.

An upper surface of each of the first polarizing portion P1 and the second polarizing portion P2 may be adjacent (for example, directly adjacent to) the adhesive layer OCR.

The first polarizing portion P1 may not overlap the light blocking layer BM in a plan view. The second polarizing portion P2 may overlap the light blocking layer BM in a plan view.

According to some embodiments, the first polarizing portion P1 may be an area other than the second polarizing portion P2 in the polarizing layer POL.

A positional relationship on a plane between the first polarizing portion P1 and the second polarizing portion P2 is shown in FIGS. 4 to 6. FIGS. 4 to 6 show a position on a plane between the first polarizing portion P1 and the second polarizing portion P2 based on the display area DA.

According to some embodiments (refer to FIG. 4), the first polarizing portion P1 may entirely cover the display area DA in a plan view. For example, the first polarizing portion P1 may cover the display area DA and at least a portion of an edge of the display area DA in a plan view. The second polarizing portion P2 may be located on one side (for example, only on one side) of the display area DA and the first polarizing portion P1. For example, the second polarizing portion P2 may be formed at a lower portion of the display area DA and the first polarizing portion P1. According to some embodiments, an area where the second polarizing portion P2 is located may correspond to an area where the driving circuit part D-IC is located.

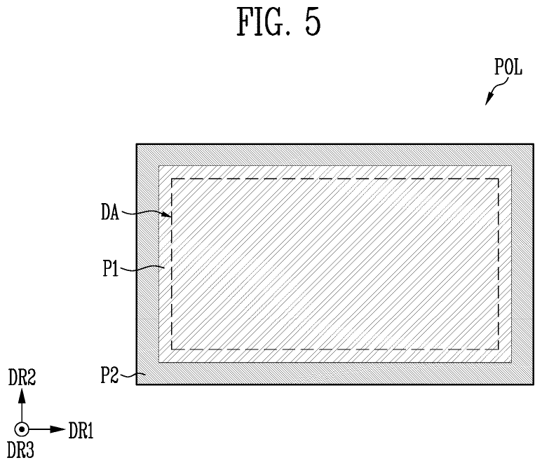

According to some embodiments (refer to FIG. 5), the second polarizing portion P2 may entirely surround the display area DA and the first polarizing portion P1 in a plan view. For example, the second polarizing portion P2 may be located on each of an upper side, a lower side, a right side, and a left side of the display area DA and the first polarizing portion P1 in a plan view. The second polarizing portion P2 may have a closed-loop structure in a plan view. According to some embodiments, an area where the second polarizing portion P2 is located may correspond to an area where the driving circuit part D-IC is located. In addition, according to some embodiments, the second polarizing portion P2 may surround all sides of the first polarizing portion P1, and even in a case where other conductive elements (for example, the touch driving circuit part and the like) are formed on some sides of the display area DA, the second polarizing portion P2 may be arranged to correspond to a position of the other conductive elements.

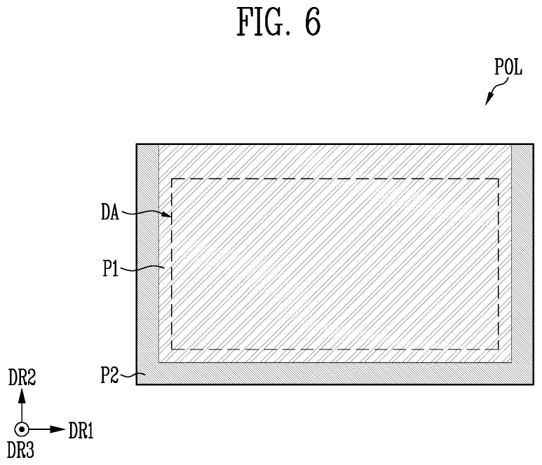

According to some embodiments (refer to FIG. 6), the second polarizing portion P2 may be located in a periphery portion of the display area DA and the first polarizing portion P1, and may not be located on one side of the display area DA and the first polarizing portion P1, in a plan view. The second polarizing portion P2 may surround two or more sides of the first polarizing portion P1 in a plan view. For example, the second polarizing portion P2 may not be located in an upper side of the display area DA and the first polarizing portion P1 in a plan view. The second polarizing portion P2 may have an open-loop structure in a plan view. According to some embodiments, an area where the second polarizing portion P2 is located may correspond to an area where the driving circuit part D-IC is located. In addition, according to some embodiments, the second polarizing portion P2 may surround two or more sides of the first polarizing portion P1, and even in a case where other conductive elements (for example, the touch driving circuit and the like) are formed on some sides of the display area DA, the second polarizing portion P2 may be arranged to correspond to a position of the other conductive elements.

The adhesive layer OCR may be arranged across the display area DA and the non-display area NDA. The adhesive layer OCR may be located on the polarizing layer POL. The adhesive layer OCR may continuously cover the first polarizing portion P1 and the second polarizing portion P2. According to some embodiments, the adhesive layer OCR may entirely cover an upper surface of the polarizing layer POL. The adhesive layer OCR may combine the polarizing layer POL, the cover glass CG, and the light blocking layer BM to each other.

The adhesive layer OCR may be provided by curing with UV light. According to some embodiments, the adhesive layer OCR may be optically clear resin (OCR). However, embodiments according to the present disclosure are not limited thereto. The adhesive layer OCR may be an optically clear adhesive (OCA) and may include various adhesive materials that may be cured by UV light.

According to some embodiments, an end of the adhesive layer OCR may overlap an end of the polarizing layer POL (for example, the second polarizing portion P2) in a plan view.

The light blocking layer BM may be located on the adhesive layer OCR in the non-display area NDA. The light blocking layer BM may overlap the adhesive layer OCR, the second polarizing portion P2, the driving circuit part D-IC, the connection film COF, and the circuit board PCB in a plan view. The light blocking layer BM may cover layers located thereunder and reduce a risk that visibility is damaged.

The light blocking layer BM may block UV light. The light blocking layer BM may include various light blocking materials. For example, the light blocking layer BM may include a black matrix material such as carbon black. However, embodiments according to the present disclosure are not limited thereto.

The cover glass CG may be arranged across the display area DA and the non-display area NDA. A lower surface of the cover glass CG may be adjacent (for example, directly adjacent to) the adhesive layer OCR in the display area DA, and may be adjacent (for example, directly adjacent to) the light blocking layer BM in the non-display area NDA. The cover glass CG may be attached to the polarizing layer POL by the adhesive layer OCR.

The cover glass CG may transmit light and may include various light-transmissive materials such as a glass material. The cover glass CG may protect other layers located thereunder. The cover glass CG may transmit UV.

The driving circuit part D-IC may be located on the display panel DP in the non-display area NDA. The driving circuit part D-IC may overlap the display panel DP, the light blocking layer BM, and the cover glass CG in a plan view.

At least a portion of the connecting film COF may be bent. A portion of the connection film COF may be located on the display panel DP, and another portion of the connection film COF may be located on the circuit board PCB. According to some embodiments, the connection film COF may be electrically connected to at least a portion of a conductive structure (for example, a line, a pad, or the like) of the display panel DP and may be electrically connected to the circuit board PCB. According to some embodiments, the connection film COF may be a chip-on-film.

The circuit board PCB may be located on a back surface of the display panel DP. The circuit board PCB may be configured to control an overall operation of the display device DD.

Alternatively, according to some embodiments, a portion of the connection film COF may not be located on the back surface of the display panel DP and may have a shape extending in a plane direction. In this case, the circuit board PCB may be located on one surface of the connection film COF and may be covered by the light blocking layer BM and the cover glass CG.

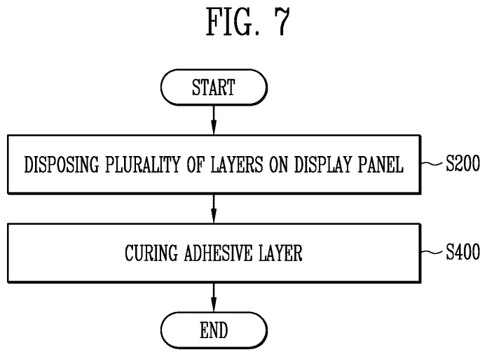

Hereinafter, a method of manufacturing the display device DD according to some embodiments is described with reference to FIGS. 7 to 9. A content that may overlap with the above-described content is briefly described or is not repeated.

FIG. 7 is a flowchart illustrating aspects of a method of manufacturing a display device according to some embodiments. Although FIG. 7 illustrates various operations in a method of manufacturing a display device, embodiments according to the present disclosure are not limited thereto, and according to various embodiments, the method may include additional operations without departing from the spirit and scope of embodiments according to the present disclosure.

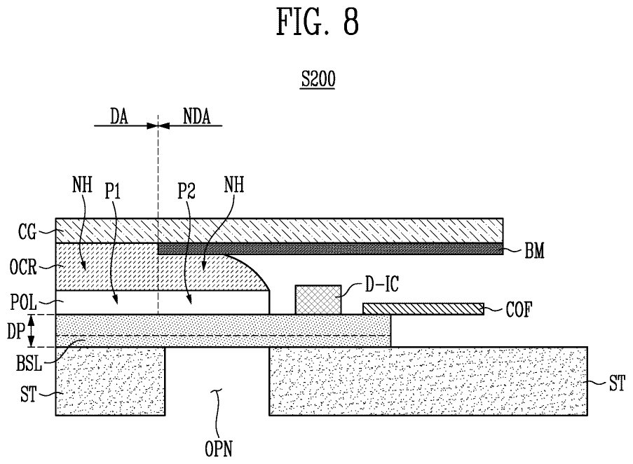

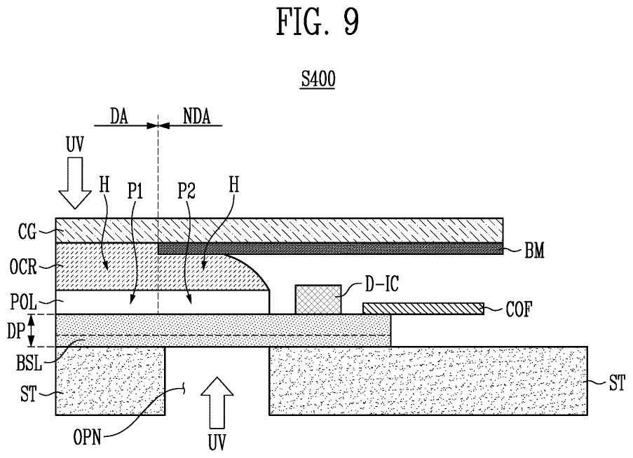

FIGS. 8 and 9 are schematic cross-sectional views for each process operation illustrating a method of manufacturing a display device according to some embodiments. FIGS. 8 and 9 are shown based on the cross-sectional structure described above with reference to FIG. 2. For convenience of description, the circuit board PCB is omitted in FIGS. 8 and 9.

Referring to FIG. 7, a method of manufacturing a display device DD according to some embodiments may include forming or arranging a plurality of layers on a display panel (S200) and curing an adhesive layer (S400).

Referring to FIGS. 7 and 8, in forming or arranging the plurality of layers on the display panel (S200), layers for forming the display device DD may be located on the display panel DP.

In this operation S200, the display panel DP may be provided. For example, in order to manufacture the display panel DP, conductive layers, insulating layers, and semiconductor layers may be patterned on the base layer BSL, and a light source such as a light emitting element may be arranged.

According to some embodiments, the conductive layer or the insulating layer on the base layer BSL may be formed based on a typical process for manufacturing a semiconductor device. For example, the conductive layer or the insulating layer on the base layer BSL may be formed by a photolithography process, etched by various methods (wet etching, dry etching, and the like), and may be deposited by various methods (sputtering, chemical vapor deposition method, and the like). The disclosure is not necessarily limited to a specific example.

In this operation S200, a plurality of layers located on the display panel DP may include the polarizing layer POL, the driving circuit part D-IC, the connection film COF, the adhesive layer OCR, the cover glass CG, and the light blocking layer BM.

In this operation S200, the display panel DP may be located on a stage ST including the opening OPN. The opening OPN may entirely pass through at least a portion of the stage ST. According to some embodiments, the display panel DP may be located on the stage ST, and a portion of a lower surface of the display panel DP may be exposed through the opening OPN.

In this operation S200, the polarizing layer POL may be located on the display panel DP, the adhesive layer OCR may be located on the polarizing layer POL, and the cover glass CG having at least a portion on which the light blocking layer BM is located may be located on the adhesive layer OCR. In this operation S200, the adhesive layer OCR may be in an uncured state NH.

In this operation S200, the first polarizing portion P1 may be located on the display panel DP in the display area DA, and the second polarizing portion P2 may be arranged to overlap the light blocking layer BM in a plan view. The second polarizing portion P2 may be arranged to overlap the opening OPN of the stage ST. Accordingly, in a plan view, the opening OPN, the second polarizing portion P2, the adhesive layer OCR, and the light blocking layer BM may overlap.

In this operation S200, the driving circuit part D-IC may be located on an area of the display panel DP where the polarizing layer POL is not located. According to some embodiments, as the light blocking layer BM is located on the adhesive layer OCR, the light blocking layer BM may be arranged to overlap the driving circuit part D-IC. According to some embodiments, the driving circuit part D-IC may not overlap the opening OPN in a plan view.

Referring to FIGS. 7 and 9, in curing the adhesive layer (S400), UV light may be applied to the adhesive layer OCR to cure the adhesive layer.

In this operation S400, the adhesive layer OCR may be in a cured state H. For example, UV light may be applied to the adhesive layer OCR including a material that may be cured based on UV light. According to some embodiments, a wavelength of the applied UV light may be in a range including about 380 nm. However, embodiments according to the present disclosure are not limited thereto.

In this operation, the UV light may include first UV light and second UV light applied in different directions. For example, the first UV light may be applied in a direction from the cover glass CG to the display panel DP (for example, a first application direction), and may cure a portion of the adhesive layer OCR overlapping the first polarizing portion P1 in a plan view. The second UV light may be applied in a direction from the display panel DP to the cover glass CG (for example, a second application direction), and may cure another portion of the adhesive layer OCR overlapping the second polarizing portion P2 in a plan view.

In this operation S400, UV light may be applied through the opening OPN to cure a portion of the adhesive layer OCR on the second polarizing portion P2. For example, UV light may be applied to the adhesive layer OCR by passing through the opening OPN, the display panel DP, and the second polarizing portion P2. As described above, the second polarizing portion P2 may transmit UV light, and thus UV light may be properly provided to a portion of the adhesive layer OCR covered by the light blocking layer BM.

In addition, according to some embodiments, in order to cure another portion of the adhesive layer OCR on the first polarizing portion P1, UV light may be applied to the adhesive layer OCR through the cover glass CG that does not overlap the light blocking layer BM. Accordingly, the adhesive layer OCR may be entirely cured.

Experimentally, as the light blocking layer BM is located in a partial area on the display panel DP, at least a portion of the adhesive layer OCR may be covered by the light blocking layer BM. In this case, properly applying UV light to a portion of the adhesive layer OCR may be difficult. In this case, because the adhesive layer OCR may not be properly cured, properly adhering layers to each other may be difficult, and a delamination risk or the like may occur, and thus a risk that structural stability of the display device DD may be damaged may occur.

However, according to some embodiments, a portion (that is, the second polarizing portion P2) of the polarizing layer POL located in an area overlapping the adhesive layer OCR covered by the light blocking layer BM may be configured to transmit UV light, and thus UV light may be applied to the adhesive layer OCR through the back surface of the display panel DP. Therefore, the adhesive layer OCR may be properly cured, the above-described risk may be reduced, and thus structural stability of the display device DD may be relatively improved.

Thereafter, according to some embodiments, the stage ST may be removed, the connection film COF may be bent, the circuit board PCB may be located on the back surface of the display panel DP, and the display device DD according to some embodiments may be provided.

The display device DD according to embodiments may be applied to various electronic devices. The electronic device 10 according to an embodiment includes the above-described display device DD and may further include other modules or devices with additional functions besides the display device DD.

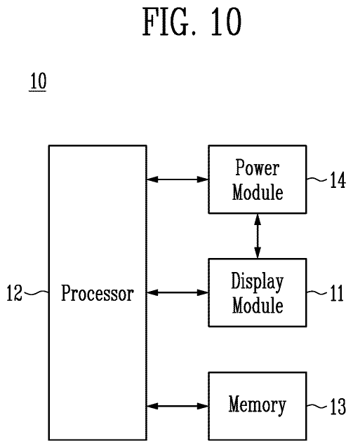

FIG. 10 is a block diagram of an electronic device according to an embodiment. Referring to FIG. 10, the electronic device 10 according to an embodiment may include a display module 11, a processor 12, memory 13, and a power module 14.

The processor 12 may include at least one of a central processing unit CPU, an application processor (AP), a graphic processing unit (GPU), a communication processor (CP), an image signal processor (ISP), and a controller.

The memory 15 may store data information needed for the operation of the processor 12 or the display module 11. When the processor 12 executes an application stored in memory 15, video data signals and/or input control signals are delivered to the display module 11 (e.g., display device DD), and the display module 11 processes the received signals to output image information through the display screen.

The power module 14 may include a power supply module, such as a power adapter or a battery device, and a power conversion module that converts the power supplied by the power supply module to generate the power needed for the operation of the electronic device 10. The power module 14 may be configured to supply power to the display module 11 (e.g., display device DD).

At least one of each component of the aforementioned electronic device 11 may be included in the display device DD according to the embodiments described above. In addition, some of the individual modules functionally included in one module may be included in the display device DD, while others may be provided separately from the display device DD. For example, the display device DD may include the display module 11, while the processor 12, memory 13, and power module 14 may be provided in the form of other devices within the electronic device 11 rather than in the display device DD.

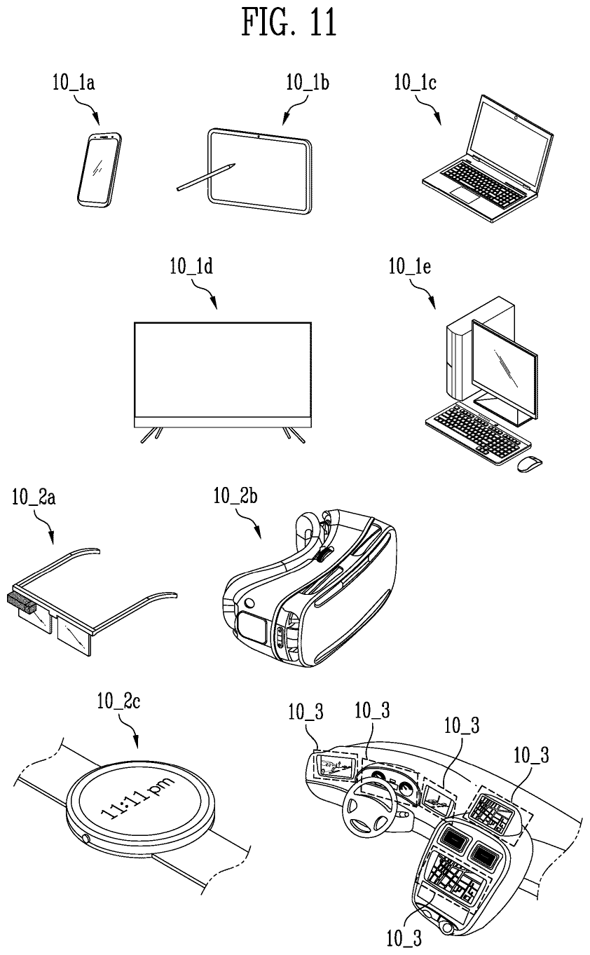

FIG. 11 shows schematic diagrams of electronic devices according to various embodiments. Referring to FIG. 11, various electronic devices to which the display device DD according to the embodiments is applied may include not only image display electronic devices such as a smartphone 10_1a, tablet PC 10_1b, laptop 10_1c, TV 10_1d, desktop monitor 10_1e, but also wearable electronic devices including a display module, such as smart glasses 10_2a, a head-mounted display 10_2b, and a smartwatch 10_2c. Additionally, it may include vehicle electronic devices with a display module, such as a CID Center Information Display arranged on the dashboard, center fascia, or dashboard of a car, or a room mirror display 10_3.

As described above, although aspects of some embodiments of the present disclosure have been described with reference to the disclosed embodiments as described above with reference to the drawings, those skilled in the art or those having a common knowledge in the art will understand that the disclosure may be variously modified and changed without departing from the spirit and scope of embodiments according to the present disclosure described in the claims, and their equivalents.

Therefore, the technical scope of embodiments according to the present disclosure should not be limited to the contents described in the detailed description of the specification, but should be defined by the claims, and their equivalents.

What is claimed is:

1. A display device comprising:
a display panel;
a polarizing layer on the display panel;
an adhesive layer on the polarizing layer; and
a light blocking layer, at least a portion of the light blocking layer being on the adhesive layer,
wherein the polarizing layer includes a first polarizing portion that does not overlap the light blocking layer and a second polarizing portion that overlaps the light blocking layer in a plan view, and
the second polarizing portion has a transmittance higher than a transmittance of the first polarizing portion with respect to ultraviolet (UV) light.

2. The display device according to claim 1, wherein the first polarizing portion blocks light having a wavelength of 380 nanometers (nm), and
the second polarizing portion transmits light having a wavelength of 380 nm.

3. The display device according to claim 1, wherein the polarizing layer includes a UV blocking portion, and
the UV blocking portion is included in the first polarizing portion and is not included in the second polarizing portion.

4. The display device according to claim 1, wherein the polarizing layer includes at least one of a triacetylcellulose (TAC) film or a polyvinyl alcohol (PVA) film.

5. The display device according to claim 1, wherein the adhesive layer includes at least one of optically clear resin (OCR) or optically clear adhesive (OCA).

6. The display device according to claim 1, further comprising:
a cover glass covering the adhesive layer and the light blocking layer,
wherein the cover glass overlaps the first polarizing portion and the second polarizing portion in the plan view, and is configured to transmit UV light.

7. The display device according to claim 1, comprising:
a display area where light is provided and a non-display area surrounding at least a portion of the display area,
wherein the first polarizing portion and the second polarizing portion are spaced apart in a direction in which the display area and the non-display area are spaced apart from each other,
the display device further comprises: a driving circuit part on an area of the display panel where the polarizing layer is not located, and
the driving circuit part is on a side of the display area and overlaps the light blocking layer in the plan view.

8. The display device according to claim 7, wherein the second polarizing portion, the adhesive layer, and the light blocking layer overlap each other in the plan view, and
the first polarizing portion and the adhesive layer overlap each other and do not overlap the light blocking layer in the plan view.

9. The display device according to claim 1, wherein the second polarizing portion is only on a side of the first polarizing portion.

10. The display device according to claim 1, wherein the second polarizing portion entirely surrounds the first polarizing portion.

11. The display device according to claim 1, wherein the second polarizing portion surrounds two or more sides of the first polarizing portion and does not surround a side.

12. The display device according to claim 1, wherein an end of the polarizing layer and an end of the adhesive layer overlap in the plan view.

13. A method of manufacturing a display device, the method comprising:
forming a plurality of layers on a display panel, the plurality of layers including a polarizing layer, an adhesive layer on the polarizing layer, and a light blocking layer, at least a portion of the light blocking layer being on the adhesive layer; and
curing the adhesive layer,
wherein the polarizing layer includes a first polarizing portion that does not overlap the light blocking layer and a second polarizing portion that overlaps the light blocking layer in a plan view, and
curing comprises applying UV light to a portion of the adhesive layer through an opening formed in a stage under the display panel and the second polarizing portion.

14. The method according to claim 13, wherein in curing, the opening does not overlap the first polarizing portion and overlaps the second polarizing portion in the plan view.

15. The method according to claim 13, wherein the light blocking layer does not overlap the first polarizing portion and overlaps the second polarizing portion in the plan view.

16. The method according to claim 13, wherein the second polarizing portion is configured to transmit UV light, and
the first polarizing portion is configured to block UV light.

17. The method according to claim 13, wherein the plurality of layers further include a cover glass covering the light blocking layer and the adhesive layer, and
the cover glass is configured to transmit UV light.

18. The method according to claim 13, wherein curing further comprises applying UV light to another portion of the adhesive layer that does not overlap the light blocking layer in a first application direction, and
the UV light applied to the portion of the adhesive layer through the opening and the second polarizing portion is applied in a second application direction different from the first application direction.

19. The method according to claim 13, wherein the plurality of layers further include a driving circuit part configured to drive a pixel included in the display panel, and
in curing, the driving circuit part does not overlap the opening and overlaps the light blocking layer in the plan view.

20. An electronic device, comprising:
a processor configured to provide input image data;
a display device configured to display an image based on the input image data; and
a power supply configured to supply power to the display device,
wherein the display device comprises:
a display panel;
a polarizing layer on the display panel;
an adhesive layer on the polarizing layer; and
a light blocking layer, at least a portion of the light blocking layer being on the adhesive layer,
wherein the polarizing layer includes a first polarizing portion that does not overlap the light blocking layer and a second polarizing portion that overlaps the light blocking layer in a plan view, and
the second polarizing portion has a transmittance higher than a transmittance of the first polarizing portion with respect to ultraviolet (UV) light.
